(19) United States
(12) Patent Application Publication
(10) Pub. No.: US 2025/0201546 A1
(43) Pub. Date: Jun. 19, 2025

(54) METHOD FOR PROCESSING SUBSTRATE, KIT FOR PROCESSING SUBSTRATE, AND METHOD FOR MANUFACTURING SEMICONDUCTOR SUBSTRATE

(71) Applicant: TOKYO OHKA KOGYO CO., LTD., Kanagawa (JP)

(72) Inventor: Takumi NAMIKI, Kanagawa (JP)

(21) Appl. No.: 18/971,492

(22) Filed: Dec. 6, 2024

Related U.S. Application Data
(60) Provisional application No. 63/609,604, filed on Dec. 13, 2023.

(51) Int. Cl. H01L 21/02; H01L 21/67

(52) U.S. Cl. CPC H01L 21/02052; H01L 21/6704

(57) ABSTRACT

There are provided a method for processing a substrate in which a surface of a pattern on a substrate is processed, the method including: a first step for processing the surface of the pattern with a first chemical solution, the first chemical solution including a silane coupling agent that has a SP value of Hansen solubility parameter of 15 or more; and a second step for processing the surface of the pattern with a second chemical solution after the first step, the second chemical solution including an anionic or amphoteric surfactant; a kit for processing a substrate; and a method for manufacturing a semiconductor substrate.

### CROSS-REFERENCE TO RELATED APPLICATIONS

The present application claims priority to U.S. Provisional application No. 63/609,604, filed with the United States Patent and Trademark Office on Dec. 13, 2023, the contents of which are incorporated herein by reference.

### TECHNICAL FIELD

The present invention relates to a method for processing a substrate, a kit for processing a substrate, and a method for manufacturing a semiconductor substrate.

### BACKGROUND ART

In recent years, the trend of high integration and miniaturization of semiconductor devices has increased, and the miniaturization and high aspect ratio of inorganic patterns on substrates are in progress. However, on the other hand, the problem of so-called pattern collapse has arisen. Pattern collapse is a phenomenon where a large number of inorganic patterns are formed in parallel on a substrate and adjacent patterns come close to each other such that they lean toward each other, and in some cases, patterns may break or peel off from the substrate. When such pattern collapse occurs, the yield and reliability of a product will be reduced.

The pattern collapse may occur due to the surface tension of a cleaning solution when the cleaning solution dries in a cleaning process carried out after the patterns are formed. For example, when a cleaning solution is removed during a drying process, stress based on the surface tension of the cleaning solution acts between patterns, causing pattern collapse.

Regarding the prevention of such pattern collapse, for example, Patent Document 1 discloses a method for processing a surface, the method including a step of processing a surface of a resin pattern provided on a substrate or an etched pattern formed by etching on a substrate, with a surface processing solution containing a silylating agent and a solvent, and a step of cleaning the resin pattern or the etched pattern after the processing with the surface processing solution.

### Patent Document

Patent Document 1: Japanese patent application laid-open No. 2010-129932

### SUMMARY OF THE INVENTION

However, in conventional technology, there is still room for improvement in the prevention of pattern collapse. The present inventor focused on that pattern collapse is particularly likely to occur after a drying process. For example, the present inventor considered that this is because patterns are prone to stick together when they are cleaned or rinsed, and the patterns are thereby prone to collapse. Hence, it is thought that such pattern collapse can be effectively prevented if high water repellency can be imparted to patterns, but in actuality, there is still room for improvement in conventional processing methods for providing water repellency because they cannot impart sufficient water repellency or they are not simple to implement.

The present invention has been made in view of the above circumstances, and it is an object of the present invention to provide a method for processing a substrate, a kit for processing a substrate, and a method for manufacturing a semiconductor substrate, which can impart high water repellency to a substrate after processing.

That is, the present invention is as follows:

<1>

A method for processing a substrate in which a surface of a pattern on a substrate is processed, the method including: a first step for processing the surface of the pattern with a first chemical solution, the first chemical solution including a silane coupling agent that has a SP value of Hansen solubility parameter of 15 or more; and a second step for processing the surface of the pattern with a second chemical solution after the first step, the second chemical solution including an anionic or amphoteric surfactant.

<2>

The method for processing the substrate according to <1>, in which the silane coupling agent includes a Si atom and an amino group (—NH₂).

<3>

The method for processing the substrate according to <1>, in which the silane coupling agent is at least one selected from the group consisting of a compound represented by formula (1a), a compound represented by formula (1b), a compound represented by formula (1c), and a compound represented by formula (1d),

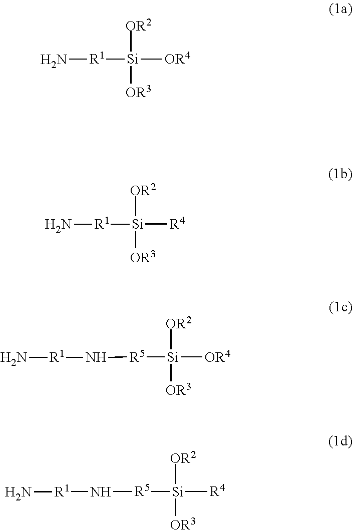

in which R¹ represents an alkylene group having 1 to 10 carbon atoms, R², R³ and R⁴ each independently represents an alkyl group having 1 to 10 carbon atoms, and R⁵ represents an alkylene group having 1 to 10 carbon atoms.

<4>

The method for processing the substrate according to <1>, in which the surfactant is at least one selected from the group consisting of a sulfonic acid-based anionic surfactant, a sulfate ester-based anionic surfactant, a carboxylic acid-based anionic surfactant, a phosphate ester-based anionic surfactant, and a carboxybetaine-based amphoteric surfactant.

<5>

The method for processing the substrate according to <1>, in which the surfactant is at least one selected from the group consisting of a compound represented by formula (2a), a compound represented by formula (2b), and a compound represented by formula (2c),

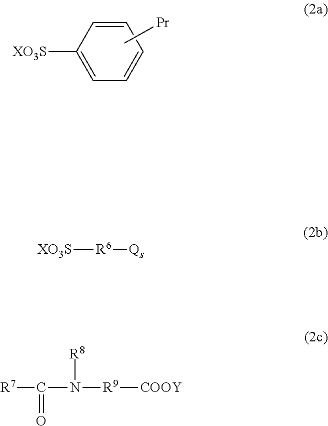

in which R⁶ represents an alkylene group, R⁷ and R⁸ each independently represents an alkyl group having 1 to 20 carbon atoms, R⁹ represents an alkylene group having 1 to 10 carbon atoms, X represents H, Na, K, or NH₄, Y represents H, Na, or K, P and Q each independently represents a monovalent organic group, r represents a number from 0 to 5, and s represents a number from 0 to 3.

<6>

The method for processing the substrate according to <1>, in which the first chemical solution includes water.

<7>

The method for processing the substrate according to <1>, in which the second chemical solution includes water.

<8>

The method for processing the substrate according to <1>, in which the first chemical solution includes a water-based organic solvent.

<9>

The method for processing the substrate according to <1>, in which the second chemical solution includes a water-based organic solvent.

<10>

The method for processing the substrate according to <1>, in which a content of the silane coupling agent in the first chemical solution is from 0.01 to 10% by mass.

<11>

The method for processing the substrate according to <1>, in which a content of the surfactant in the second chemical solution is from 0.01 to 10% by mass.

<12>

A kit for processing a substrate, the kit being for processing a surface of an etched pattern on a substrate, the kit including: a first chemical solution that is used for processing the surface of the pattern, the first chemical solution including a silane coupling agent that has a SP value of Hansen solubility parameter of 15 or more; and a second chemical solution that is used for processing the surface of the pattern after the surface of the pattern is processed with the first chemical solution, the second chemical solution including an anionic or amphoteric surfactant.

<13>

A method for manufacturing a semiconductor substrate, including: a step for preparing a substrate with an etched pattern, and a step for processing a surface of the pattern of the substrate by the method for processing the substrate according to <1>.

### DETAILED DESCRIPTION OF THE INVENTION

Hereinafter, an embodiment for carrying out the present invention (hereinafter simply referred to as “the present embodiment”) will be described in detail. The present embodiment below is an example for explaining the present invention, and it is not intended to limit the present invention to the following description. The present invention may be implemented with any appropriate modification within the scope of its gist.

### <Method for Processing a Substrate>

A method for processing a substrate according to the present embodiment is a method for processing a substrate in which a surface of a pattern on a substrate is processed, the method including: a first step for processing the surface of the pattern with a first chemical solution, the first chemical solution including a silane coupling agent that has a SP value of Hansen solubility parameter of 15 or more; and a second step for processing the surface of the pattern with a second chemical solution after the first step, the second chemical solution including an anionic or amphoteric surfactant. By such a processing method, high water repellency can be imparted to a substrate, and as a result, pattern collapse can be effectively prevented. Although the reason therefore is not certain, it is considered to be as follows.

First, in the first step, the silane coupling agent in the first chemical solution makes the potential of a surface of a substrate positive. Then, in the second step, the substrate is processed with the anionic or amphoteric surfactant in the second chemical solution, and bulky coordination is formed. It is considered that hydrophobic groups of the surfactant can thus make the surface of the substrate water repellent (However, the mechanism and effect according to the present embodiment are not limited thereto.).

The processing method according to the present embodiment can be suitably used for a processing solution for removing an etching residue containing an inorganic substance. For example, in recent years, miniaturization of patterns of a semiconductor (fine patterns) and 3D integration have been developing, and the aspect ratio of patterns has become higher. Such fine patterns and high aspect ratio patterns tend to cause pattern collapse. In particular, pattern collapse is likely to occur after a drying process. This is considered to be because, for example, when patterns are cleaned or rinsed, they are prone to stick together, and when dried after the cleaning or rinsing, the patterns are prone to collapse even when a slight external force (for example, capillary force or surface tension of a liquid such as a cleaning solution, a rinsing solution or the like) is applied. However, since the processing method according to the present embodiment is a simple method that can be carried out at normal temperature and normal pressure and can impart high water repellency to patterns, it is possible to effectively prevent patterns from sticking together, and as a result, it is possible to effectively prevent pattern collapse (However, the mechanism and effect according to the present embodiment are not limited thereto.).

### (First Step)

In the first step, a surface of a pattern is processed with a first chemical solution that contains a silane coupling agent having a SP value of Hansen solubility parameter of 15 or more. A substrate to be processed may include, for example, a semiconductor wafer, a substrate for a liquid crystal display, a substrate for a plasma display, a substrate for a FED (Field Emission Display), a substrate for an optical disk, a substrate for a magnetic disk, a substrate for a magneto-optical disk, a substrate for a photomask, a ceramic substrate, and a substrate for a solar cell, etc.

The first chemical solution contains the silane coupling agent having a SP value of Hansen solubility parameter of 15 or more. The silane coupling agent may be contained in the first chemical solution as a salt. Specific examples of the salt may include, but are not particularly limited to, a sodium salt, a potassium salt, an ammonium salt, an alkylammonium salt (for example, a tetramethylammonium salt, etc.), and the like.

The SP value of Hansen solubility parameter herein is a value obtained by dividing the solubility parameter introduced by Hildebrand into three parameters, the dispersion term OD, the polarity term OP, and the hydrogen bond term OH, and plotting a point in a three-dimensional space (Hansen space, HSP space).

The dispersion term δD represents the effect due to dispersion force, the polarity term δP represents the effect due to dipole-dipole force, and the hydrogen bond term OH represents the effect due to hydrogen bond force.

δD: The energy derived from dispersion forces between molecules (the dispersion term)

δP: The energy derived from polar forces between molecules (the polarity term)

δH: The energy derived from hydrogen bond forces between molecules (the hydrogen bond term)

The unit of each of the terms is MPa^{0.5}.

There is a relationship between Hildebrand's SP value and Hansen's HSP as shown below.

(Hildebrand's SP)²=δD²+δP²+δH²

Suitable examples of the silane coupling agent having a SP value of 15 or more may include the followings. Needless to say, the silane coupling agent used in the present embodiment is not limited to those below.

TABLE 1

| | | δ D | | δ H | |
|---|---|---|---|---|---|
| | | (Dispersion | δ P | (Hydrogen | SP |
| Reagent | logP | term) | (Polarity) | bond) | value |
| APTES | 2.604 | 14.1 | 3.9 | 4 | 15.2 |
| APDES | 0.033 | 14.3 | 3.8 | 4 | 15.3 |
| AEAPTES | 2.176 | 14.2 | 3.9 | 5 | 15.6 |
| APDMS | −0.986 | 14.4 | 4.1 | 5 | 15.8 |
| APTMS | 1.076 | 14.2 | 4.2 | 5.4 | 15.8 |
| AEAPTMS | 0.648 | 14.3 | 4.1 | 6.4 | 16.2 |
| AEAPDMS | −1.414 | 14.6 | 4.1 | 6 | 16.3 |
| AHAPTMS | 2.19 | 14.1 | 3.4 | 4.8 | 15.3 |
| MTMS | 1.653 | 14.1 | 3.9 | 4.1 | 15.2 |
| DIW | — | 15.5 | 16 | 42.3 | 47.8 |

APTES: 3-aminopropyltriethoxysilane

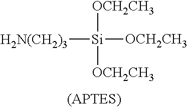

APDES: 3-aminopropyldiethoxymethylsilane

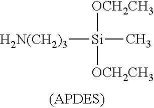

AEAPTES: 3-(2-aminoethylamino) propyltriethoxysilane

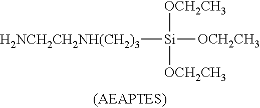

APDMS: 3-aminopropyldimethoxymethylsilane

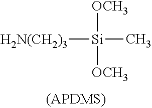

APTMS: 3-aminopropyltrimethoxysilane

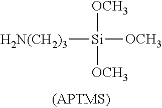

· AEAPTMS: 3-(2-aminoethylamino) propyltrimethoxysilane

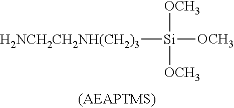

AEAPDMS: 3-(2-aminoethylamino) propyldimethoxymethylsilane

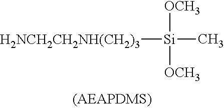

AHAPTMS: 3-(6-aminohexylamino) propyltrimethoxysilane

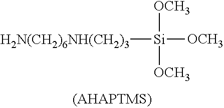

MTMS: methyltrimethoxysilane

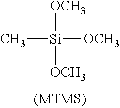

As the silane coupling agent, a silane coupling agent containing a Si atom and an amino group (—NH₂) is preferable. This silane coupling agent has a SP value of 15 or more. The silane coupling agent with such structure can efficiently react with —OH groups on a substrate. Hence, even when a surface layer of a substrate has-OH groups due to the presence of a natural oxide film formed on a surface of the substrate (for example, TiN, etc.), such silane coupling agent can bond therewith by hydrolysis. Therefore, the silane coupling agent with the structure can impart even higher water repellency. Furthermore, even in the case of a pattern substrate that does not contain a silicon atom, the silane coupling agent with the structure is preferable because the silane coupling agent can bond with the substrate due to the presence of the natural oxide film described above (However, the mechanism and effect according to the present embodiment are not limited thereto.).

The silane coupling agent is more preferably at least one selected from the group consisting of a compound represented by formula (1a), a compound represented by formula (1b), a compound represented by formula (1c), and a compound represented by formula (1d). These silane coupling agents have the following structures respectively and have a SP value of 15 or more.

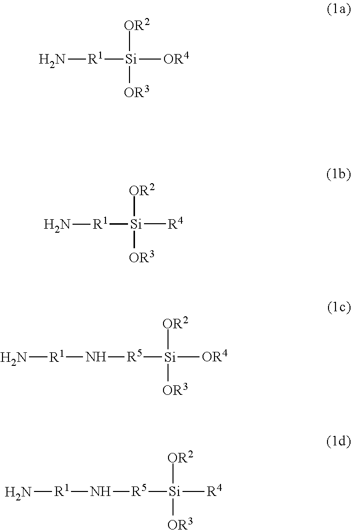

(In the formulae, R¹ represents an alkylene group having 1 to 10 carbon atoms, R², R³ and R⁴ each independently represents an alkyl group having 1 to 10 carbon atoms, and R⁵ represents an alkylene group having 1 to 10 carbon atoms.)

R¹ is an alkylene group having 1 to 10 carbon atoms. The lower limit of the number of carbon atoms is preferably 2 or more. The upper limit of the number of carbon atoms is preferably 5 or less, and more preferably 4 or less. The alkylene group may be linear or branched, but is preferably linear. Preferred specific examples of R¹ may include, for example, linear alkylene groups such as —(CH₂)₅—, —(CH₂)₄—, —(CH₂)₃—, —(CH₂)₂—, —(CH₂)—, etc.

R², R³ and R⁴ are each an alkyl group having 1 to 10 carbon atoms. The upper limit of the number of carbon atoms is preferably 5 or less, more preferably 4 or less, even more preferably 3 or less, and still even more preferably 2 or less. The alkyl group may be linear or branched, but is preferably linear. Preferred specific examples of R², R³ and R⁴ may include, for example, linear alkyl groups such as —(CH₂)₄—CH₃, —(CH₂)₃—CH₃, —(CH₂)₂—CH₃, —CH₂—CH₃, —CH₃, etc.

R⁵ is an alkylene group having 1 to 10 carbon atoms. The lower limit of the number of carbon atoms is preferably 2 or more. The upper limit of the number of carbon atoms is preferably 5 or less, and more preferably 4 or less. The alkylene group may be linear or branched, but is preferably linear. Preferred specific examples of R⁵ may include, for example, linear alkylene groups such as —(CH₂)₅—, —(CH₂)₄—, —(CH₂)₃—, —(CH₂)₂—, —(CH₂)—, etc.

Preferred specific examples of the compound represented by formula (1a) may include 3-aminopropyltriethoxysilane (APTES), 3-aminopropyltrimethoxysilane (APTMS), etc.

Preferred specific examples of the compound represented by formula (1b) may include 3-aminopropyldiethoxymethylsilane (APDES), 3-aminopropyldimethoxymethylsilane (APDMS), etc.

Preferred specific examples of the compound represented by formula (1c) may include 3-(2-aminoethylamino) propyltriethoxysilane (AEAPTES), 3-(2-aminoethylamino) propyltrimethoxysilane (AEAPTMS), 3-(6-aminohexylamino) propyltriethoxysilane, 3-(6-aminohexylamino) propyltrimethoxysilane (AHAPTMS), etc.

Preferred specific examples of the compound represented by formula (1d) may include 3-(2-aminoethylamino) propyldiethoxymethylsilane, 3-(2-aminoethylamino) propyldimethoxymethylsilane (AEAPDMS), etc.

The content of the silane coupling agent in the first chemical solution is preferably from 0.01 to 10% by mass. The lower limit of the content is more preferably 0.05% by mass or more, even more preferably 0.1% by mass or more, still even more preferably 0.5% by mass or more, and further more preferably 1% by mass or more. The upper limit of the content is more preferably 8% by mass or less, even more preferably 6% by mass or less, still even more preferably 4% by mass or less, and further more preferably 3% by mass or less.

The first chemical solution preferably contains water. As the water, for example, deionized water (DIW), ultrapure water (UPW), pure water, high-purity ionized water, and the like can be used from the viewpoint of being suitable for manufacturing a semiconductor device. The first chemical solution is more preferably a water-based chemical solution containing water as a solvent.

The water content of the first chemical solution is preferably 50% by mass or more and 99.99% by mass or less. The lower limit of the content is more preferably 60% by mass or more, even more preferably 70% by mass or more, still even more preferably 80% by mass or more, further more preferably 90% by mass or more, and still further more preferably 95% by mass or more. The upper limit of the content is more preferably 99.9% by mass or less, even more preferably 99.5% by mass or less, and still even more preferably 99% by mass or less. The water content within the above numerical range can provide water solubility as a water-based processing solution, maintain water repellency imparted to a substrate and etching residue removal properties at high levels, and allow another component to be uniformly and stably dissolved.

The first chemical solution preferably contains a water-based organic solvent. It is preferable that the water-based organic solvent be at least one selected from the group consisting of, for example, an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent.

Furthermore, it is more preferable that the processing solution according to the present embodiment contain water and/or a hydrophilic organic solvent as a solvent and do not contain a solvent other than these.

Specific examples of the alcohol-based solvent may include aliphatic alcohols such as methanol, ethanol, modified ethanol, isopropanol (IPA: also known as isopropyl alcohol), n-propanol, n-butanol, 3-methoxy-3-methyl-1-butanol, etc.; glycols such as ethylene glycol, diethylene glycol, propylene glycol, dipropylene glycol, glycerin, 1,3-propanediol, 1,3-butanediol, 1,4-butanediol, furfuryl alcohol, hexylene glycol, etc.; and the like.

Specific examples of the glycol ester-based solvent may include ethylene-based glycol ethers such as ethylene glycol monomethyl ether, ethylene glycol dimethyl ether, diethylene glycol monomethyl ether, diethylene glycol dimethyl ether, triethylene glycol monomethyl ether, triethylene glycol dimethyl ether, ethylene glycol monoethyl ether, ethylene glycol diethyl ether, ethylene glycol monobutyl ether, ethylene glycol dibutyl ether, diethylene glycol monobutyl ether, diethylene glycol dibutyl ether, triethylene glycol monobutyl ether, triethylene glycol dibutyl ether, ethylene glycol monohexyl ether, ethylene glycol dihexyl ether, diethylene glycol monohexyl ether, diethylene glycol dihexyl ether, ethylene glycol-phenyl ether, etc.; ethylene-based glycol ether acetates such as ethylene glycol monobutyl ether acetate, diethylene glycol monobutyl ether acetate, etc.; propylene-based glycol ethers such as propylene glycol monomethyl ether (PGME), propylene glycol dimethyl ether, dipropylene glycol monomethyl ether (DPM), dipropylene glycol dimethyl ether, tripropylene glycol monomethyl ether, tripropylene glycol dimethyl ether, propylene glycol monoethyl ether, propylene glycol diethyl ether, dipropylene glycol monoethyl ether, dipropylene glycol diethyl ether, tripropylene glycol monoethyl ether, tripropylene glycol diethyl ether, propylene glycol monopropyl ether, propylene glycol dipropyl ether, dipropylene glycol monopropyl ether, dipropylene glycol dipropyl ether, propylene glycol monobutyl ether, propylene glycol dibutyl ether, dipropylene glycol monobutyl ether, dipropylene glycol dibutyl ether, tripropylene glycol monobutyl ether, tripropylene glycol dibutyl ether, propylene glycol phenyl ether, etc.; propylene-based glycol ether acetates such as propylene glycol methyl ether acetate (PGMEA: also known as propylene glycol monomethyl ether acetate), dipropylene glycol methyl ether acetate, propylene glycol diacetate, etc.; and the like.

Specific examples of the sulfoxide-based solvent may include dimethyl sulfoxide (DMSO), diethyl sulfoxide, dipropyl sulfoxide, diphenyl sulfoxide, thiophene, and the like.

Specific examples of the sulfone-based solvent may include dimethyl sulfone, diethyl sulfone, tetramethylene sulfone, dipropyl sulfone, sulfolane (also known as tetramethylene sulfone), 3-methylsulfolane, 2,4-dimethylsulfolane, 3,4-dimethylsulfolane, diphenylsulfolane, 3,4-diphenylmethylsulfolane, sulfolene, 3-methylsulfolene, 3-ethylsulfolene, and the like.

Specific examples of the amide-based solvent may include N, N-dimethylformamide (DMF), diethylformamide (DEF), N, N-dimethylacetamide (DMAc), N-methylpyrrolidine (MPD), hexamethylphosphate triamide (HMPA), and the like.

Specific examples of the lactone-based solvent may include γ-butyrolactone, α-methyl-γ-butyrolactone, β-propiolactone, γ-valerolactone, 8-valerolactone, γ-caprolactone, ε-caprolactone, γ-laurolactone, hexanolactone, and the like.

Specific examples of the imidazolidinone-based solvent may include 2-imidazolidinone, 1,3-dimethyl-2-imidazolidinone, 1,3-diethyl-2-imidazolidinone, 1,3-dipropyl-2-imidazolidinone, 1,3-diisopropyl-2-imidazolidinone, and the like.

Specific examples of the nitrile-based solvent may include acetonitrile, propionitrile, valeronitrile, butyronitrile, and the like.

Specific examples of the ketone-based solvent may include acetone, methyl ethyl ketone (MEK), methyl isobutyl ketone (MIBK), diisobutyl ketone, cyclohexanone, diacetone alcohol, 1-hexanone, 2-hexanone, 4-heptanone, 2-heptanone (methylamyl ketone), 1-octanone, 2-octanone, 1-nonanone, 2-nonanone, acetylacetone, acetonyl acetone, phenylacetone, acetophenone, methylnaphthyl ketone, methylcyclohexanone, ionone, isophorone, propylene carbonate, diacetonyl alcohol, acetylcarbinol, and the like.

Specific examples of the ether-based solvent may include diisopropyl ether, 1,4-dioxane, methyl-tert-butyl ether (MTBE), dimethyl ether, diethyl ether, dipropyl ether, methylphenyl ether, and the like.

Specific examples of the ester-based solvent may include methyl acetate, ethyl acetate, butyl acetate, amyl acetate, propyl acetate, isopropyl acetate, methyl lactate, ethyl lactate, butyl lactate, ethyl methoxyacetate, ethyl ethoxyacetate, acetic acid 2-methoxybutyl (2-methoxybutyl acetate), acetic acid 3-methoxybutyl (3-methoxybutyl acetate), acetic acid 4-methoxybutyl (4-methoxybutyl acetate), acetic acid 3-methoxy-3-methylbutyl (3-methoxy-3-methylbutyl acetate), acetic acid 3-ethyl-3-methoxybutyl (3-ethyl-3-methoxybutyl acetate), 4-methyl-4-methoxypentyl acetate, methyl formate, ethyl formate, propyl formate, butyl formate, ethyl lactate (EL), propyl lactate, butyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, and the like.

Specific examples of the pyrrolidone-based solvent may include N-methylpyrrolidone (NMP), 2-pyrrolidone, N-vinyl-2-pyrrolidone, and the like.

Specific examples of the urea-based solvent may include 1,3-dimethylurea, 1,3-diethylurea, 1,3-dipropylurea, 1,3-diisopropylurea, tetramethylurea, tetraethylurea, tetrapropylurea, tetraisopropylurea, N, N-dimethylpropylene urea, and the like.

Among the above, as the water-based organic solvent of the first chemical solution, alcohols such as isopropanol (IPA: also known as isopropyl alcohol), ethanol, ethylene glycol, propylene glycol, glycerin, 1,3-propanediol, 1,3-butanediol, 1,4-butanediol, diethylene glycol, dipropylene glycol, furfuryl alcohol, hexylene glycol, etc.; glycol ester-based solvents such as diethylene glycol monobutyl ether, propylene glycol monomethyl ether (PGME), propylene glycol methyl ether acetate (PGMEA: also known as propylene glycol monomethyl ether acetate), etc.; dimethyl sulfoxide; ethers such as ethylene glycol dimethyl ether, diethylene glycol dimethyl ether, triethylene glycol dimethyl ether, tetraethylene glycol dimethyl ether, propylene glycol dimethyl ether, etc.; morpholines such as N-methylmorpholine N-oxide, etc. are preferable, for example.

By using such a suitable water-based organic solvent, it can be expected to further improve the anticorrosive properties of metal layers containing various metal components as a main component. Furthermore, when such a solvent is used, it can be expected to reduce damage (film loss) caused to various metal layers without impairing etching residue removal properties.

The water-based organic solvent may be used alone or in combination of two or more.

The content of the water-based organic solvent in the first chemical solution is preferably 50% by mass or more and 99.99% by mass or less in total. The lower limit of the content is more preferably 60% by mass or more, even more preferably 70% by mass or more, still even more preferably 80% by mass or more, further more preferably 90% by mass or more, and still further more preferably 95% by mass or more. The upper limit of the content is more preferably 99.9% by mass or less, even more preferably 99.5% by mass or less, and still even more preferably 99% by mass or less. The content of the water-based organic solvent within the above range can allow another component to be uniformly and stably dissolved, provide water solubility as a water-based processing solution, and maintain water repellency imparted to a substrate and etching residue removal properties at high levels.

When water and the water-based organic solvent are used in combination in the first chemical solution, the sum of the water content and the water-based organic solvent content is preferably 50% by mass or more and 99.99% by mass or less. The lower limit of the sum is more preferably 60% by mass or more, even more preferably 70% by mass or more, still even more preferably 80% by mass or more, further more preferably 90% by mass or more, and still further more preferably 95% by mass or more. The upper limit of the sum is more preferably 99.9% by mass or less, even more preferably 99.5% by mass or less, and still even more preferably 99% by mass or less. The sum of the water content and the water-based organic solvent content within the above range can allow another component to be uniformly and stably dissolved, provide water solubility as a water-based processing solution, and maintain water repellency imparted to a substrate and etching residue removal properties at high levels.

When water and the water-based organic solvent are used in combination in the first chemical solution, the mass ratio of water to the water-based organic solvent (water: the water-based organic solvent) is preferably from 1:99 to 99:1, more preferably from 5:95 to 95:5, and even more preferably from 10:90 to 90:10. The mass ratio of water to the water-based organic solvent within the above range can allow another component to be uniformly and stably dissolved, provide water solubility as a water-based processing solution, and maintain water repellency imparted to a substrate and etching residue removal properties at high levels.

For the processing of a substrate in the first step, a known method may be employed, such as a method of immersing a substrate in a processing solution, a method of applying a processing solution to a substrate, etc. Examples of the cleaning operation may include a method of continuously discharging a processing solution on a substrate rotating at a constant speed (rotational application method), a method of immersing a substrate in a processing solution for a certain period of time (dipping method), a method of spraying a processing solution on a surface of a substrate (spraying method), etc. Among these, a method of immersing a substrate in a processing solution is preferable.

Conditions for the processing using the processing solution in the first step may be suitably selected in consideration of a material of the substrate, the composition of the first chemical solution, etc. Processing conditions for immersing a substrate in the processing solution may usually be an immersion at a processing temperature from 10 to 40° C. and for a processing time of 10 seconds or more and 30 minutes or less. The lower limit of the processing temperature is preferably 15° C. or more, and more preferably 20° C. or more. The upper limit of the processing temperature is preferably 30° C. or less, and more preferably 28° C. or less. The lower limit of the processing time is preferably 20 seconds or more, and more preferably 30 seconds or more. The upper limit of the processing time is preferably 10 minutes or less, and more preferably 5 minutes or less.

### (Other Components)

The first chemical solution may or may not contain another component as a component other than the above components as necessary. Examples of the other component may include a buffer, a pH adjuster, an anticorrosive agent, etc.

### (Buffer)

The first chemical solution may contain a buffer. A buffer is a compound that has a mechanism of inhibiting a change in the pH of a processing solution. By containing a buffer, the processing solution can be efficiently controlled such that the pH of the processing solution is at a predetermined value. The buffer is not particularly limited as long as it is a compound having pH buffering ability.

Examples of the buffer may include Good's buffer. The Good's buffer is not particularly limited, and a known one can be used.

The buffer may be used alone or in combination of two or more.

### (pH Adjuster)

The first chemical solution may contain a pH adjuster to adjust to a desired pH. As the pH adjuster, an inorganic acid, an organic acid, an organic basic compound, and an inorganic basic compound can be appropriately used.

### (Anticorrosive Agent)

The first chemical solution may contain an anticorrosive agent. Examples of the anticorrosive agent may include a nitrogen-containing aromatic compound, etc. For example, the nitrogen-containing aromatic compound is preferably at least one selected from the group consisting of an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, and a phenanthroline ring-containing compound.

Examples of the imidazole ring-containing compound may include, for example, imidazole, 1-decyl-3-methylimidazolium chloride, 2-ethyl-4-methylimidazole, 2-methylimidazole, 2-ethylimidazole, 2-isopropylimidazole, 2-propylimidazole, 2-butylimidazole, 4-methylimidazole, 2,4-dimethylimidazole, 2-undecylimidazole, 2-aminoimidazole, 2,2′-biimidazole, and the like.

Examples of the triazole ring-containing compound may include, for example, 1,2,4-triazole (TAZ), 1, 2, 3-benzotriazole (BTA), 1,2,3-triazole, 3-amino-1H-1,2,4-triazole, 5-methyl-1H-benzotriazole (5MBTA), 1-hydroxybenzotriazole, 1-hydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1, 2, 3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, 3-aminotriazole, and the like.

Examples of the carbazole ring-containing compound may include, for example, 9H-carbazole, 4-hydroxycarbazole, 1-methyl-carbazole, 3-methyl-9H-carbazole, 9-methyl-1H-carbazole, 2-methoxycarbazole, 1-bromocarbazole, 2-bromocarbazole, 3-bromocarbazole, 4-bromocarbazole, 2-chlorocarbazole, 3-chlorocarbazole, 2-fluorocarbazole, 3-fluorocarbazole, 2-iodocarbazole, 3-iodocarbazole, 9-acetylcarbazole, 2,7-dibromocarbazole, 3,6-dibromocarbazole, 3,6-dichlorocarbazole, 2,3-benzcarbazole, 9-acetyl-3,6-diiodocarbazole, 2-bromo-7-methoxy-9H-carbazole, 3,6-dimethylcarbazole, 2,7-dimethylcarbazole, 3,6-diaminocarbazole, 3-amino-ethylcarbazole, 3,6-dimethoxy-9H-carbazole, 2,7-dimethoxy-9H-carbazole, 3,3′-bicarbazole, 7H-benzo[c]carbazole, and the like.

Examples of the pyridine ring-containing compound may include, for example, 4-(3-phenylpropyl) pyridine, 1H-1, 2, 3-triazolo[4,5-b]pyridine, 1,2,4-triazolo[4,3-a]pyridin-3 (2H)-one, 3H-1, 2, 3-triazolo[4,5-b]pyridin-3-ol, 1-acetyl-1H-1, 2, 3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,2′-bipyridyl, 4,4′-dimethyl-2,2′-bipyridyl, 4,4′-di-tert-butyl-2,2′-bipyridyl, 4,4′-dinonyl-2,2′-bipyridyl, and the like.

Examples of the pyrimidine ring-containing compound may include, for example, pyrimidine, 4-methylpyrimidine, 1,2,4-triazolo[1,5-a]pyrimidine, 1, 3, 4, 6, 7, 8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2, 4, 6-trimethoxypyrimidine, 2, 4, 6-triphenylpyrimidine, 2, 4-diamino-6-hydroxylpyrimidine, 2, 4-diaminopyrimidine, 2-acetamidopyrimidine, 2-aminopyrimidine, 2-methyl-5,7-diphenyl-(1, 2, 4) triazolo (1, 5-a) pyrimidine, 2-methylsulfanyl-5, 7-diphenyl-(1, 2, 4) triazolo (1, 5-a) pyrimidine, 2-methylsulfanyl-5, 7-diphenyl-4, 7-dihydro-(1, 2, 4) triazolo (1, 5-a) pyrimidine, 4-aminopyrazolo[3,4-d]pyrimidine, and the like.

Examples of the tetrazole ring-containing compound may include, for example, 1H-tetrazole, 5-amino-1H-tetrazole, 5-methyl-1H-tetrazole, 5-phenyl-1H-tetrazole, 1-(2-diaminoethyl)-5-mercaptotetrazole, and the like.

Examples of the pyrazole ring-containing compound may include, for example, 3,5-dimethylpyrazole, 3-amino-5-methylpyrazole, 4-methylpyrazole, 3-amino-5-hydroxypyrazole, and the like.

Examples of the purine ring-containing compound may include, for example, purine, adenine, N6-benzoyladenine, and the like.

Examples of the phenanthroline ring-containing compound may include, for example, 1,10-phenanthroline, 5-amino-1, 10-phenanthroline, and the like.

The anticorrosive agent may also be a salt of the compounds described above. Specific examples of the salt may include, but are not particularly limited to, a sodium salt, a potassium salt, an ammonium salt, an alkylammonium salt (for example, a tetramethylammonium salt, etc.), and the like. It may also be a hydrate of the above compounds.

The anticorrosive agent may be used alone or in combination of two or more.

### (Impurity, Etc.)

The first chemical solution may contain a metal impurity containing at least one metal atom selected from the group consisting of a Fe atom, a Cr atom, a Ni atom, a Zn atom, a Ca atom, a Pb atom, etc., for example.

The total content of the metal atom in the first chemical solution is preferably 100 ppt by mass or less with respect to the total mass of the processing solution. The lower the lower limit of the total content of the metal atom, the more preferable it is. For example, the lower limit may be 0.001 ppt by mass or more. The total content of the metal atom may for example be from 0.001 ppt by mass to 100 ppt by mass. The total content of the metal atom equal to or lower than the above preferred upper limit improves defect prevention properties and residue prevention properties of the processing solution. It is considered that, with the total content of the metal atom equal to or higher than the above preferred lower limit, the metal atom is less likely to be a free atom in the system and less likely to have a negative impact on the production yield of an entire object to be cleaned.

The content of the metal impurity can be adjusted by, for example, a purification process such as filtering, etc. The purification process such as filtering, etc. may be performed on a part or all of the raw materials before preparation of the processing solution, or may be performed after preparation of the processing solution.

The first chemical solution may contain, for example, an impurity derived from an organic substance (organic impurity). The total content of the organic impurity in the processing method according to the present embodiment is preferably 5000 ppm by mass or less. The lower the lower limit of the content of the organic impurity, the more preferable it is. For example, the lower limit may be 0.1 ppm by mass or more. The total content of the organic impurity may for example be from 0.1 ppm by mass to 5000 ppm by mass.

The first chemical solution may contain an object to be counted of such a size as counted by a light scattering liquid-borne particle counter, for example. The size of the object to be counted is, for example, 0.04 μm or more. The number of the object to be counted contained in the first chemical solution is, for example, 1,000 or less per 1 mL of the processing solution, and the lower limit value is, for example, 1 or more. It is considered that the number of the object to be counted in the chemical solution within the above-described range improves a metal corrosion suppression effect of the chemical solution.

The organic impurity and/or the object to be counted described above may be added to the chemical solution or may be inevitably mixed in the chemical solution in the manufacturing process of the chemical solution. As non-limiting examples of the case that the organic impurity and/or the object to be counted is inevitably mixed in the manufacturing process of the chemical solution, the organic impurity may be contained in a raw material (for example, an organic solvent) used for manufacturing the chemical solution, or may be mixed in from an external environment in the manufacturing process of the chemical solution (for example, contamination).

In the case that the object to be counted is added to the chemical solution, the abundance ratio may be adjusted for each specific size in consideration of the surface roughness of an object to be cleaned, etc.

### (Second Step)

In the second step, the surface of the pattern is processed with a second chemical solution containing an anionic or amphoteric surfactant after the first step.

The second chemical solution contains an anionic surfactant or an amphoteric surfactant. Examples of the anionic surfactant may include a sulfonic acid-type anionic surfactant, a sulfate ester-type anionic surfactant, a carboxylic acid-type anionic surfactant, a phosphate ester-type anionic surfactant, and the like. Examples of the amphoteric surfactant may include a carboxybetaine-type amphoteric surfactant, and the like. These surfactants may be contained in the second chemical solution as a salt. Specific examples of the salt may include, but are not particularly limited to, a sodium salt, a potassium salt, an ammonium salt, an alkylammonium salt (for example, a tetramethylammonium salt, etc.), and the like.

The surfactant in the second chemical solution comes into contact with the surface of the substrate whose potential was made positive by the silane coupling agent in the first chemical solution in the first step, and the surfactant is coordinated in a bulky manner on the surface of the substrate, so that the surface of the substrate can be water repellent by hydrophobic groups of the surfactant.

The surfactant of the second chemical solution preferably contains at least one selected from the group consisting of a sulfonic acid-type anionic surfactant, a sulfate ester-type anionic surfactant, a carboxylic acid-type anionic surfactant, a phosphate ester-type anionic surfactant, and a carboxybetaine-type amphoteric surfactant. More preferably, the surfactant of the second chemical solution is an anionic surfactant.

More preferably, the surfactant of the second chemical solution contains at least one selected from the group consisting of a compound represented by formula (2a), a compound represented by formula (2b), and a compound represented by formula (2c),

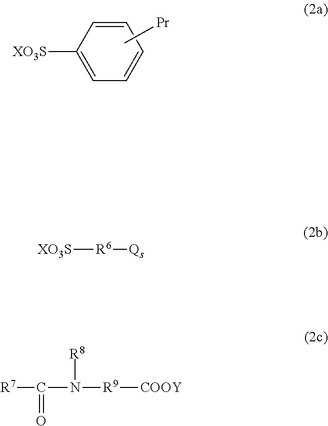

(In the formulae, R⁶ represents an alkylene group, R⁷ and R⁸ each independently represents an alkyl group having 1 to 20 carbon atoms, and R⁹ represents an alkylene group having 1 to 10 carbon atoms. X represents H, Na, K, or NH₄, and Y represents H, Na, or K. P and Q each independently represents a monovalent organic group. r represents a number from 0 to 5, and s represents a number from 0 to 3.).

R⁶ is an alkylene group. The number of carbon atoms is preferably from 1 to 30. The lower limit of the number of carbon atoms is more preferably 5 or more, even more preferably 7 or more, and still even more preferably 10 or more. The upper limit of the number of carbon atoms is more preferably 27 or less, even more preferably 25 or less, and still even more preferably 23 or less. The alkylene group may be linear or branched, but is preferably linear.

R⁷ is an alkyl group having 1 to 20 carbon atoms. The lower limit of the number of carbon atoms is preferably 3 or more, more preferably 5 or more, even more preferably 7 or more, and still even more preferably 10 or more. The upper limit of the number of carbon atoms is more preferably 16 or less, even more preferably 14 or less, and still even more preferably 13 or less. The alkyl group may be linear or branched, but is preferably linear. Preferred specific examples of R⁷ may include CH₃ (CH₂)₅—, CH₃ (CH₂)₆—, CH₃ (CH₂)₇—, CH₃ (CH₂)₈—, CH₃ (CH₂)₉—, CH₃ (CH₂)₁₀—, CH₃ (CH₂)₁₁—, CH₃ (CH₂)₁₂—, CH₃ (CH₂)₁₃—, etc.

R⁸ is an alkyl group having 1 to 20 carbon atoms. The upper limit of the number of carbon atoms is preferably 16 or less, more preferably 14 or less, even more preferably 10 or less, still even more preferably 6 or less, further preferably 4 or less, further more preferably 3 or less, and still further more preferably 2 or less. The alkyl group may be linear or branched, but is preferably linear. Preferred specific examples of R⁸ may include CH₃—, CH₃ (CH₂)—, CH₃ (CH₂)₃—, CH₃ (CH₂)₄—, CH₃ (CH₂)₅—, CH₃ (CH₂)₆—, etc.

R⁹ is an alkylene group having 1 to 10 carbon atoms. The upper limit of the number of carbon atoms is more preferably 8 or less, even more preferably 5 or less, still even more preferably 4 or less, further more preferably 3 or less, and still further more preferably 2 or less. The alkylene group may be linear or branched, but is preferably linear. Preferred specific examples of R⁹ may include-(CH₂)₅—, —(CH₂)₄—, —(CH₂)₃—, —(CH₂)₂—, —(CH₂)—, etc.

X is H, Na, K, or NH₄. These may be present as ions in the second chemical solution. For example, the case where X is NH₄ also encompasses a case where the terminal H₄NO₃S— is contained in the second chemical solution as ions, NH₄⁺ and SO₃⁻.

Y is H, Na, or K. These may be present as ions in the second chemical solution. For example, the case where Y is Na also encompasses a case where the terminal —COONa is contained in the second chemical solution as ions, —COO⁻ and Na⁺.

P is a monovalent organic group. Examples of the organic group may include a substituted or unsubstituted alkyl group. A specific example of P is preferably an alkyl group having 1 to 20 carbon atoms. The alkyl group may be linear or branched, but is preferably linear. The lower limit of the number of carbon atoms in the alkyl group is preferably 5 or more, more preferably 7 or more, and even more preferably 10 or more. The upper limit of the number of carbon atoms in the alkyl group is preferably 17 or less, more preferably 15 or less, and even more preferably 13 or less.

Q is a monovalent organic group. Examples of the organic group may include a substituted or unsubstituted alkyl group. A specific example of Q is preferably an alkyl group having 1 to 5 carbon atoms. The alkyl group may be linear or branched, but is preferably linear. The upper limit of the number of carbon atoms in the alkyl group is preferably 4 or less, more preferably 3 or less, and even more preferably 2 or less.

r is a number from 0 to 5. The lower limit of r is preferably 1 or more. The upper limit of r is preferably 3 or less, and more preferably 2 or less. Even more preferably, r is 1.

s is a number from 0 to 3. The lower limit of s is preferably 1 or more. The upper limit of s is preferably 3 or less, and more preferably 2 or less. Even more preferably, s is 1.

Preferred specific examples of the compound represented by formula (2a) may include dodecyl diphenyl ether disulfonic acid, dodecyl benzene sulfonic acid, salts thereof, etc. Examples thereof may include dodecyl diphenyl ether disulfonic acid, dodecyl diphenyl ether disulfonic acid ammonium salt (see formula (2a-1) below), dodecyl diphenyl ether disulfonic acid sodium salt, dodecyl benzene sulfonic acid (DBSA, see formula (2a-2) below), dodecyl benzene sulfonic acid ammonium salt, dodecyl benzene sulfonic acid sodium salt, etc.

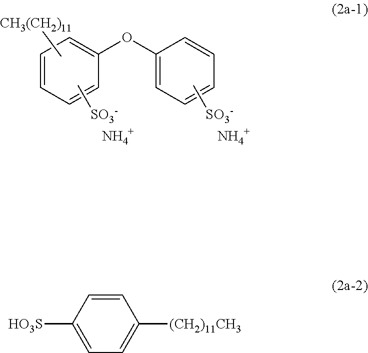

Preferred specific examples of the compound represented by formula (2b) may include an alkylsulfonic acid, a salt thereof, etc. Examples thereof may include an alkylsulfonic acid, an alkylsulfonic acid ammonium salt, an alkylsulfonic acid sodium salt, etc. Examples of the alkylsulfonic acid may include a compound represented by the formula: R—SO₃H (wherein R represents an alkyl group), etc.

Preferred specific examples of the compound represented by formula (2c) may include N-lauroylsarcosine, a salt thereof, etc. Examples thereof may include N-lauroylsarcosine, a N-lauroylsarcosine ammonium salt, a N-lauroylsarcosine sodium salt, etc.

The content of the anionic surfactant or the amphoteric surfactant in the second chemical solution is preferably from 0.01 to 10% by mass. The lower limit of the content is more preferably 0.05% by mass or more, even more preferably 0.1% by mass or more, still even more preferably 0.5% by mass or more, and further more preferably 1% by mass or more. The upper limit of the content is more preferably 8% by mass or less, even more preferably 6% by mass or less, still even more preferably 4% by mass or less, and further more preferably 3% by mass or less.

The second chemical solution preferably contains water. More preferably, the second chemical solution is a water-based chemical solution containing water as a solvent. The water content of the second chemical solution is preferably 50% by mass or more and 99.99% by mass or less. The lower limit of the content is more preferably 60% by mass or more, even more preferably 70% by mass or more, still even more preferably 80% by mass or more, further more preferably 90% by mass or more, and still further more preferably 95% by mass or more. The upper limit of the content is more preferably 99.9% by mass or less, even more preferably 99.5% by mass or less, still even more preferably 99% by mass or less. The water content within the above range can provide water solubility as a water-based processing solution, allow another component to be uniformly and stably dissolved, and maintain water repellency imparted to a substrate and etching residue removal properties at high levels.

The second chemical solution preferably contains a water-based organic solvent. It is preferable that the water-based organic solvent be at least one selected from the group consisting of, for example, an alcohol-based solvent, a glycol ester-based solvent, a sulfoxide-based solvent, a sulfone-based solvent, an amide-based solvent, a lactone-based solvent, an imidazolidinone-based solvent, a nitrile-based solvent, a ketone-based solvent, an ether-based solvent, an ester-based solvent, a pyrrolidone-based solvent, and a urea-based solvent. Regarding specific examples of these solvents, those mentioned above as solvents that can be used in the first chemical solution can be used.

Furthermore, it is more preferable that the second chemical solution contain water and/or a hydrophilic organic solvent as a solvent and do not contain a solvent other than these.

As the water-based organic solvent of the second chemical solution, alcohols such as isopropanol (IPA: also known as isopropyl alcohol), ethanol, ethylene glycol, propylene glycol, glycerin, 1,3-propanediol, 1,3-butanediol, 1,4-butanediol, diethylene glycol, dipropylene glycol, furfuryl alcohol, hexylene glycol, etc.; glycol ester-based solvents such as diethylene glycol monobutyl ether, propylene glycol monomethyl ether (PGME), propylene glycol methyl ether acetate (PGMEA: also known as propylene glycol monomethyl ether acetate), etc.; dimethyl sulfoxide; ethers such as ethylene glycol dimethyl ether, diethylene glycol dimethyl ether, triethylene glycol dimethyl ether, tetraethylene glycol dimethyl ether, propylene glycol dimethyl ether, etc.; morpholines such as N-methylmorpholine N-oxide, etc. are preferable, for example.

By using such a suitable water-based organic solvent, it can be expected to further improve the anticorrosive properties of metal layers containing various metal components as a main component. Furthermore, when such a solvent is used, it can be expected to further effectively reduce damage (film loss) caused to various metal layers without impairing etching residue removal properties.

The water-based organic solvent may be used alone or in combination of two or more.

The content of the water-based organic solvent of the second chemical solution is preferably 50% by mass or more and 99.99% by mass or less in total. The lower limit of the content is more preferably 60% by mass or more, even more preferably 70% by mass or more, still even more preferably 80% by mass or more, further more preferably 90% by mass or more, and still further more preferably 95% by mass or more. The upper limit of the content is more preferably 99.9% by mass or less, even more preferably 99.5% by mass or less, and still even more preferably 99% by mass or less. The content of the water-based organic solvent within the above range can allow another component to be uniformly and stably dissolved, provide water solubility as a water-based processing solution, and maintain water repellency imparted to a substrate and etching residue removal properties at high levels.

When water and the water-based organic solvent are used in combination in the second chemical solution, the sum of the water content and the water-based organic solvent content is preferably 50% by mass or more and 99.99% by mass or less. The lower limit of the sum is more preferably 60% by mass or more, even more preferably 70% by mass or more, still even more preferably 80% by mass or more, further more preferably 90% by mass or more, and still further more preferably 95% by mass or more. The upper limit of the sum is more preferably 99.9% by mass or less, even more preferably 99.5% by mass or less, and still even more preferably 99% by mass or less. The sum of the water content and the water-based organic solvent content within the above range can allow another component to be uniformly and stably dissolved, provide water solubility as a water-based processing solution, and maintain water repellency imparted to a substrate and etching residue removal properties at high levels.

When water and the water-based organic solvent are used in combination in the second chemical solution, the mass ratio of water to the water-based organic solvent (water: the water-based organic solvent) is preferably from 1:99 to 99:1, more preferably from 5:95 to 95:5, and even more preferably from 10:90 to 90:10. The mass ratio of water to the water-based organic solvent within the above range can allow another component to be uniformly and stably dissolved, provide water solubility as a water-based processing solution, and maintain water repellency imparted to a substrate and etching residue removal properties at high levels.

For the processing of the substrate in the second step, a known method may be employed, such as a method of immersing a substrate in a processing solution, a method of applying a processing solution to a substrate, etc., but a method of immersing a substrate in a processing solution is preferable.

Conditions for the processing using the processing solution in the second step may be suitably selected in consideration of a material of the substrate, the composition of the first chemical solution, etc. Processing conditions for immersing a substrate in the processing solution may usually be an immersion at a processing temperature from 10 to 40° C. and for a processing time of 10 seconds or more and 30 minutes or less. The lower limit of the processing temperature is preferably 15° C. or more, and more preferably 20° C. or more. The upper limit of the processing temperature is preferably 30° C. or less, and more preferably 28° C. or less. The lower limit of the processing time is preferably 20 seconds or more, and more preferably 30 seconds or more. The upper limit of the processing time is preferably 10 minutes or less, and more preferably 5 minutes or less.

### (Other Components)

The second chemical solution may or may not contain another component as a component other than the above components as necessary. Examples of the other component may include a buffer, a pH adjuster, an anticorrosive agent, etc.

### (Buffer)

The second chemical solution may contain a buffer. As the buffer, those mentioned above as buffers that can be blended in the first chemical solution can be appropriately employed. By containing a buffer, the processing solution can be efficiently controlled such that the pH of the processing solution is at a predetermined value. The buffer is not particularly limited as long as it is a compound having pH buffering ability.

### (pH Adjuster)

The second chemical solution may contain a pH adjuster to adjust to a desired pH. As the pH adjuster, an inorganic acid, an organic acid, an organic basic compound, and an inorganic basic compound can be appropriately used. As the pH adjuster, those mentioned above as pH adjusters that can be blended in the first chemical solution can be appropriately employed.

### (Anticorrosive Agent)

The second chemical solution may contain an anticorrosive agent. Examples of the anticorrosive agent may include a nitrogen-containing aromatic compound, etc. For example, the nitrogen-containing aromatic compound is preferably at least one selected from the group consisting of an imidazole ring-containing compound, a triazole ring-containing compound, a carbazole ring-containing compound, a pyridine ring-containing compound, a pyrimidine ring-containing compound, a tetrazole ring-containing compound, a pyrazole ring-containing compound, a purine ring-containing compound, and a phenanthroline ring-containing compound. As the anticorrosive agent, those mentioned above as anticorrosive agents that can be blended in the first chemical solution can be appropriately employed.

### (Impurity, Etc.)

The second chemical solution may contain a metal impurity containing at least one metal atom selected from the group consisting of a Fe atom, a Cr atom, a Ni atom, a Zn atom, a Ca atom, a Pb atom, etc., for example.

The total content of the metal atom in the second chemical solution is preferably 100 ppt by mass or less with respect to the total mass of the processing solution. The lower the lower limit of the total content of the metal atom, the more preferable it is. For example, the lower limit may be 0.001 ppt by mass or more. The total content of the metal atom may for example be from 0.001 ppt by mass to 100 ppt by mass. The total content of the metal atom equal to or lower than the above preferred upper limit improves defect prevention properties and residue prevention properties of the processing solution. It is considered that, with the total content of the metal atom equal to or higher than the above preferred lower limit, the metal atom is less likely to be a free atom in the system and less likely to have a negative impact on the production yield of an entire object to be cleaned.

The content of the metal impurity can be adjusted by, for example, a purification process such as filtering, etc. The purification process such as filtering, etc. may be performed on a part or all of the raw materials before preparation of the processing solution, or may be performed after preparation of the processing solution.

The second chemical solution may contain, for example, an impurity derived from an organic substance (organic impurity). The total content of the organic impurity in the processing method according to the present embodiment is preferably 5000 ppm by mass or less. The lower the lower limit of the content of the organic impurity, the more preferable it is. For example, the lower limit may be 0.1 ppm by mass or more. The total content of the organic impurity may for example be from 0.1 ppm by mass to 5000 ppm by mass.

The second chemical solution may contain an object to be counted of such a size as counted by a light scattering liquid-borne particle counter, for example. The size of the object to be counted is, for example, 0.04 μm or more. The number of the object to be counted contained in the second chemical solution is, for example, 1,000 or less per 1 mL of the processing solution, and the lower limit value is, for example, 1 or more. It is considered that the number of the object to be counted in the chemical solution within the above-described range improves a metal corrosion suppression effect of the chemical solution.

The organic impurity and/or the object to be counted described above may be added to the chemical solution or may be inevitably mixed in the chemical solution in the manufacturing process of the chemical solution. As non-limiting examples of the case that the organic impurity and/or the object to be counted is inevitably mixed in the manufacturing process of the chemical solution, the organic impurity may be contained in a raw material (for example, an organic solvent) used for manufacturing the chemical solution, or may be mixed in from an external environment in the manufacturing process of the chemical solution (for example, contamination).

In the case that the object to be counted is added to the chemical solution, the abundance ratio may be adjusted for each specific size in consideration of the surface roughness of an object to be cleaned, etc.

### (Other Steps)

The processing method according to the present embodiment may include another step in addition to the first step and the second step. For example, before the first step, a cleaning step for cleaning a substrate with an acidic chemical solution or an alkaline chemical solution may be performed. Before the first step, a rinsing step for rinsing a substrate with water or a water-based organic solvent may be performed. The rinsing step is preferably performed after performing the above cleaning step and before performing the first step. Furthermore, after the second step, a rinsing step for rinsing the substrate with water or a water-based organic solvent may be performed.

Examples of the acidic chemical solution used in the cleaning step may include hydrogen fluoride (hydrofluoric acid in the case of a solution), a hydrogen peroxide solution, etc. Examples of the alkaline chemical solution used in the cleaning step may include hydroxylamine, ethanolamine, etc. Cleaning conditions for the cleaning step are not particularly limited, and suitable conditions may be selected as appropriate, taking into consideration the material, shape, etc. of a substrate to be cleaned. The cleaning step can remove particles, etc. on a substrate.

As the water-based organic solvent used in the rinsing step, it is possible to use a water-based organic solvent that can be used in the first chemical solution and the second chemical solution, but it is preferable to use alcohols, etc. By performing the rinsing step, a chemical cleaned in the cleaning step can be washed away. As the rinsing step, a known method such as a shower method, an overflow method, a quick dump rinse method, etc. can be employed.

In either case where the rinsing step is performed before the first step or where the rinsing step is performed after the second step, the rinsing may be performed with the conditions and methods described above.

When a step other than the first step and the second step is performed, it is preferable to perform the second step after the first step is performed. As described above, in the processing method according to the present embodiment, a surface of a substrate is changed to a positive potential in the first step, and thereafter the surface is processed with the surfactant contained in the second chemical solution in the second step, so that water repellency can be imparted to the substrate and the surfactant can be coordinated in a bulky manner. From this viewpoint, it is preferable that no cleaning or rinsing step, etc. be involved between the first step and the second step. Furthermore, it is more preferable that the second step be performed continuously after the first step.

Regarding the removal of residues, for example, the processing method according to the present embodiment can be expected to efficiently remove residues contained in a hard mask layer (HM layer) and another layer of a substrate. For example, the processing method according to the present embodiment is also expected to efficiently remove an inorganic substance-containing residue derived from a metal wiring layer that contains one selected from the group consisting of a metal described below, and a metal oxide, a metal nitride, a metal chloride, and a metal fluoride thereof.

Examples of the metal may include one of metals such as molybdenum (Mo), tungsten (W), ruthenium (Ru), copper (Cu), gold (Au), silver (Ag), iron (Fe), nickel (Ni), aluminum (Al), lead (Pb), zinc (Zn), tin (Sn), tantalum (Ta), magnesium (Mg), cobalt (Co), bismuth (Bi), cadmium (Cd), titanium (Ti), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), thallium (Tl), etc.; a metal oxide, a metal nitride, a metal chloride, a metal fluoride, etc. thereof; and the like. Examples of the inorganic substance other than metals may include silicon (Si), an oxide (SiOx; Unless otherwise specified, x represents a number.) and a nitride (SiNx) thereof, and the like.

The processing method according to the present embodiment can be applied to substrates with various configurations. The substrate to be processed may include, for example, a semiconductor wafer, a substrate for a liquid crystal display, a substrate for a plasma display, a substrate for a FED (Field Emission Display), a substrate for an optical disk, a substrate for a magnetic disk, a substrate for a magneto-optical disk, a substrate for a photomask, a ceramic substrate, and a substrate for a solar cell, etc. This layer may be metal wiring, an etching stop layer, an interlayer insulating film, and various other functional layers, or may be a film such as a so-called oxide film. One example of the substrate may be a silicon-based substrate for manufacturing a semiconductor.

The processing method according to the present embodiment is suitable for cleaning a semiconductor substrate after dry etching is performed in a wiring process.

### <Kit for Processing a Substrate>

The first chemical solution and the second chemical solution described above can also be suitably used as a kit for processing a substrate. That is, a preferred example of a kit for processing a substrate according to the present embodiment may be a kit for processing a substrate, the kit being for processing a surface of an etched pattern on a substrate, the kit including: a first chemical solution that is used for processing the surface of the pattern, the first chemical solution including a silane coupling agent that has a SP value of Hansen solubility parameter of 15 or more; and a second chemical solution that is used for processing the surface of the pattern after the surface of the pattern is processed with the first chemical solution, the second chemical solution including an anionic or amphoteric surfactant. By using the first chemical solution and the second chemical solution according to the procedure of the processing method described above, high water repellency can be imparted to a substrate, and pattern collapse can be effectively prevented. Regarding the procedure, the methods and conditions explained for the above-described substrate processing method can be employed.

### <Method for Manufacturing a Semiconductor Substrate>

The processing method according to the present embodiment and a processing method using the same can be suitably used as a method for manufacturing a semiconductor substrate. A preferred example of a method for manufacturing a semiconductor substrate according to the present embodiment may be a method for manufacturing a semiconductor substrate, including: (1) a step for preparing a substrate with an etched pattern, and (2) a step for processing a surface of the pattern of the substrate by the above-described method for processing the substrate.

For the step (1), a known method and conditions may be employed for etching a substrate. The etching method is not particularly limited, may be wet etching or dry etching, but is preferably dry etching. In the case of dry etching, it is advantageous from the viewpoints that metal wiring at nano level is possible, and gas used can be controlled. In the case of dry etching, damage to the substrate, etc. tends to be relatively large, but by using the processing method according to the present embodiment, it is expected that such damage can be effectively reduced.

In the case of dry etching, plasma may be used. Usually, when plasma etching is performed, there are a problem that the substrate is prone to damage, and a problem that plasma etching residues are generated and need to be cleaned with a processing solution. However, it is preferable that such problems can be effectively prevented by using the processing method according to the present embodiment.

In the step (2), the substrate may be processed in a method employing the above-mentioned conditions. Needless to say, a step other than the first step using the first chemical solution and the second step using the second chemical solution may be performed. For example, a cleaning step for cleaning the substrate with an acidic chemical solution or an alkaline chemical solution may be performed after the step (1) and before the first step in the step (2). Similarly, a rinsing step for rinsing the substrate with water or a water-based organic solvent may be performed after the step (1) and before the first step in the step (2). The rinsing step is preferably performed after performing the above cleaning step and before performing the first step. Furthermore, a rinsing step for rinsing the substrate with water or a water-based organic solvent may be performed after the second step in the step (2). Through these steps, a semiconductor substrate can be obtained. The semiconductor substrate obtained by the manufacturing method according to the present embodiment can be used as a material for various electronic devices, including a semiconductor integrated circuit, etc.

As described above, the method for processing the substrate according to the present embodiment can impart high water repellency to the processed substrate. As a result, pattern collapse can be effectively prevented. In particular, it is possible to effectively prevent the problem that patterns are prone to collapse in a drying step after the substrate is cleaned and/or rinsed. Furthermore, regarding the substrate to be processed, high collapse prevention effect can be expected even for substrates with fine patterns that are prone to collapse, such as patterns miniaturized to a process node of 10 nm or less (for example, 10 nm, 7 nm, 5 nm, 3 nm, etc.), patterns with a high aspect ratio, etc.

As described above, the method for processing the substrate according to the present embodiment requires only that the second step be performed after the first step, and it is possible to carry out these steps at normal temperature and normal pressure. Therefore, the processing method according to the present embodiment is expected to have the advantages of being a simple method and not requiring a large-scale device configuration. In addition, since it is possible to prevent the occurrence of defective products due to pattern collapse, it can also contribute to improving the yield.

Furthermore, since the first chemical solution and the second chemical solution used in the method for processing the substrate, the kit, and the method for manufacturing the semiconductor substrate according to the present embodiment may be halogen-free chemical solutions, not only is it environmentally friendly, but it can also be suitable in terms of ease of disposal.

### Examples

The present invention will be described in more detail with reference to the following Examples and Comparative examples, but the present invention is not limited in any way to the following examples.

### <Reagents Used>

The abbreviations of the reagents used are described below. The SP values of the reagents used in the first chemical solution are shown in Table 1 above.
APTES: 3-Aminopropyltriethoxysilane
APDES: 3-Aminopropyldiethoxymethylsilane
AEAPTES: 3-(2-Aminoethylamino) propyltriethoxysilane)
“A200” (anionic surfactant, dodecyl diphenyl ether disulfonic acid ammonium salt, “Paionin A200”, TAKEMOTO OIL & FAT CO., LTD.)
“A32Q” (anionic surfactant, alkylsulfonic acid having a linear alkyl group having 10 to 20 carbon atoms, “Takesurf A-32-Q”, TAKEMOTO OIL & FAT CO., LTD.)
“DBSA” (anionic surfactant, dodecylbenzenesulfonic acid)
N-Lauroylsarcosine sodium salt (anionic surfactant)
“Triton (trademark) X-405” (nonionic surfactant, polyethylene glycol octylphenyl ether)
Decyltrimethylammonium chloride (cationic surfactant)
DIW: Deionized water
IPA: Isopropanol (also known as isopropyl alcohol)
PGMEA: Propylene glycol methyl ether acetate (also known as propylene glycol monomethyl ether acetate)

### Examples 1 to 28, Reference Example, Comparative Examples 1 to 6

First chemical solutions and second chemical solutions were prepared by blending the components shown in the tables in the ratios shown in the tables. For example, in Example 1, a first chemical solution containing 3% by mass of “APTES” in deionized water (DIW) as a solvent, and a second chemical solution containing 1% by mass of “A200” in deionized water as a solvent were prepared. For example, in Example 9, a first chemical solution containing 3% by mass of “APTES” and 0.5% by mass of “AMM” in deionized water (DIW) as a solvent, and a second chemical solution containing 1% by mass of “A200” in deionized water as a solvent were prepared. For example, in Example 15, a first chemical solution containing 3% by mass of “APTES” in deionized water (DIW) as a solvent, and a second chemical solution containing 1% by mass of “A200” in a mixed solvent of deionized water and isopropanol in a ratio of 1:9 (deionized water: isopropanol, by mass) were prepared.

First, a laminate was prepared by forming a TEOS film (tetraethoxysilane, Si(OC₂H₅)₄, film thickness: 100 nm) on a substrate (silicon substrate) by a plasma CVD method. The laminate was cut into a size of 1 cm×2 cm in top view to fabricate test samples (wafer coupons).

Similarly, a laminate (substrate/SiN film) was prepared by forming a SiN film (silicon nitride film, SiN, film thickness: 100 nm) on a substrate (silicon substrate) by the plasma CVD method. The laminate was cut into a size of 1 cm×2 cm in top view to fabricate test samples (wafer coupons).

Then, the samples (substrate/TEOS film and substrate/SiN film) were cleaned for one minute with hydrofluoric acid (0.1% by mass aqueous solution of hydrogen fluoride (HF)). Next, the samples were rinsed with deionized water (DIW). The samples were then immersed in the first chemical solution at 25° C. for one minute to be processed (first step). Subsequently, the samples were immersed in the second chemical solution at 25° C. for one minute to be processed (second step). Then, the samples were raised out and rinsed with deionized water. The samples were further rinsed with isopropanol. Lastly, the samples were dried by blowing nitrogen gas.

For each of the samples after the processings, the contact angle (CA) of TEOS and the contact angle (CA) of SiN were measured. The contact angles are contact angles of water (deionized water: DIW) on surfaces of the TEOS film and the SiN film. The contact angles are values measured at a temperature of 23° C. and a humidity of 50% and obtained by dropping a water droplet on the surfaces of the TEOS film and the SiN film with a microsyringe and measuring the angles (unit: °) one minute after the dropping with a contact angle meter (manufactured by Kyowa Interface Science Co., Ltd, device name: DM-501).

Tables 2 to 4 present the conditions of the first and second chemical solutions used and the evaluation results for Examples 1 to 28, Reference example, and Comparative examples 1 to 6. In the tables, the notation “-” for the first and second chemical solutions indicates that no processing using the corresponding chemical solution was performed. In the tables, the notation “/” indicates that the components were used in combination. In addition, “%” and the mixing ratios of the solvents in the tables are based on mass. For example, “DIW/PGMEA (9:1)” indicates a mixed solvent containing deionized water (DIW) and PGMEA in a mass ratio of 9:1.

In Examples 26 to 28, the effect of pH was examined. In Example 26, the second chemical solution was prepared under the standard conditions without pH adjustment. In Examples 27 and 28, the second chemical solution was prepared under conditions in which the pH was adjusted to the acidic region (pH 3.3, see Example 27) or the alkaline region (pH 9.8, see Example 28) by adding an acid or an amine. As is clear from the table below, it was at least confirmed that, in all of Examples 26 to 28, excellent properties were obtained independently of the pH.

TABLE 2

| | First chemical solution | | Second chemical solution | | CA on | CA on |
|---|---|---|---|---|---|---|
| | Component | Solvent | Component | Solvent | TEOS | SiN |
| Example 1 | 3% APTES | DIW | 1% A200 | DIW | 91.5 | 90.7 |
| Example 2 | 1% APTES | DIW | 1% A200 | DIW | 88.0 | 85.7 |
| Example 3 | 2% APTES | DIW | 1% A200 | DIW | 91.9 | 87.1 |
| Example 4 | 3% APTES | DIW | 0.1% A200 | DIW | 91.5 | 87.5 |
| Example 5 | 3% APTES | DIW | 0.3% A200 | DIW | 91.8 | 90.7 |
| Example 6 | 3% APTES | DIW | 0.5% A200 | DIW | 91.0 | 90.2 |
| Example 7 | 1% APDES | DIW | 1% A200 | DIW | 64.2 | 57.2 |
| Example 8 | 1% AEAPTES | DIW | 1% A200 | DIW | 90.5 | 88.3 |
| Example 9 | 3% APTES/0.5% AMM | DIW | 1% A200 | DIW | 91.3 | 89.0 |
| Example 10 | 3% APTES/0.5% AcOH | DIW | 1% A200 | DIW | 89.8 | 89.1 |
| Example 11 | 3% APTES | DIW/IPA(1:9) | 1% A200 | DIW | 94.0 | 90.4 |
| Example 12 | 3% APTES | DIW/IPA(5:5) | 1% A200 | DIW | 92.3 | 89.6 |
| Example 13 | 3% APTES | DIW/IPA(9:1) | 1% A200 | DIW | 94.0 | 90.2 |
| Example 14 | 3% APTES | DIW/PGMEA(9:1) | 1% A200 | DIW | 93.5 | 88.3 |

TABLE 3

| | First chemical solution | | Second chemical solution | | CA on | CA on |
|---|---|---|---|---|---|---|
| | Component | Solvent | Component | Solvent | TEOS | SiN |
| Example 15 | 3% APTES | DIW | 1% A200 | DIW/IPA(1:9) | 93.4 | 89.1 |
| Example 16 | 3% APTES | DIW | 1% A200 | DIW/IPA(5:5) | 92.9 | 87.9 |
| Example 17 | 3% APTES | DIW | 1% A200 | DIW/IPA(9:1) | 93.3 | 89.9 |
| Example 18 | 3% APTES | DIW | 0.3% A32Q | DIW | 89.0 | 89.2 |
| Example 19 | 3% APTES | DIW | 0.5% A32Q | DIW | 91.4 | 88.7 |
| Example 20 | 3% APTES | DIW | 1% A32Q | DIW | 91.1 | 90.1 |
| Example 21 | 3% APTES | DIW/IPA(9:1) | 1% A32Q | DIW | 91.9 | 90.9 |
| Example 22 | 3% APTES | DIW | 0.15% A200/0.15% A32Q | DIW | 90.8 | 87.7 |
| Example 23 | 3% APTES | DIW | 0.25% A200/0.25% A32Q | DIW | 91.1 | 89.3 |
| Example 24 | 3% APTES | DIW | 0.3% DBSA | DIW | 82.6 | 72.0 |
| Example 25 | 3% APTES | DIW | 0.1% N-Lauroyisarcosine sodium salt | DIW | 87.3 | 71.5 |
| Example 26 | 3% APTES | DIW | 0.3% A200 | DIW (std pH 7.0) | 93.0 | 89.9 |
| Example 27 | 3% APTES | DIW | 0.3% A200 | DIW (pH 3.3) | 93.3 | 88.5 |
| Example 28 | 3% APTES | DIW | 0.3% A200 | DIW (pH 9.8) | 92.1 | 89.6 |

TABLE 4

| | First chemical solution | | Second chemical solution | | CA on | CA on |
|---|---|---|---|---|---|---|
| | Component | Solvent | Component | Solvent | TEOS | SiN |
| Reference example 1 | — | — | — | — | <10 | 14.1 |
| Comparative example 1 | 1% APTES | DIW | — | — | 10.6 | <10 |
| Comparative example 2 | — | — | 1% A200 | DIW | <10 | <10 |
| Comparative example 3 | 1% APDES | DIW | — | — | 34.4 | <10 |
| Comparative example 4 | 1% AEAPTES | DIW | — | — | 15.5 | <10 |
| Comparative example 5 | 3% APTES | DIW | 1% Triton X-405 | DIW | 35.5 | 24.1 |
| Comparative example 6 | 3% APTES | DIW | 1% Decyltrimethylammonium Chloride | DIW | 23.6 | 13.4 |

From the above, it was at least confirmed that, according to the present Examples, the processing methods of the Examples can impart high water repellency to a film. By processing a substrate with such a processing solution, it is possible to impart high water repellency to a film formed on the substrate, and it is also expected that pattern collapse of the substrate after processing can be effectively prevented (collapse prevention).

1. A method for processing a substrate in which a surface of a pattern on a substrate is processed, the method comprising:
a first step for processing the surface of the pattern with a first chemical solution, the first chemical solution comprising a silane coupling agent that has a SP value of Hansen solubility parameter of 15 or more; and
a second step for processing the surface of the pattern with a second chemical solution after the first step, the second chemical solution comprising an anionic or amphoteric surfactant.

2. The method for processing the substrate according to claim 1,
wherein the silane coupling agent comprises a Si atom and an amino group (—NH₂).

3. The method for processing the substrate according to claim 1,
wherein the silane coupling agent is at least one selected from the group consisting of a compound represented by formula (1a), a compound represented by formula (1b), a compound represented by formula (1c), and a compound represented by formula (1d), 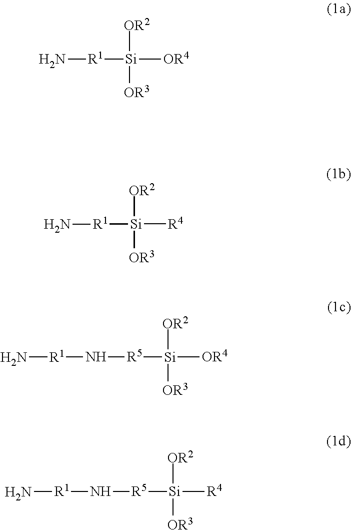
wherein R¹ represents an alkylene group having 1 to 10 carbon atoms, R², R³ and R⁴ each independently represents an alkyl group having 1 to 10 carbon atoms, and R⁵ represents an alkylene group having 1 to 10 carbon atoms.

4. The method for processing the substrate according to claim 1,
wherein the surfactant is at least one selected from the group consisting of a sulfonic acid-based anionic surfactant, a sulfate ester-based anionic surfactant, a carboxylic acid-based anionic surfactant, a phosphate ester-based anionic surfactant, and a carboxybetaine-based amphoteric surfactant.

5. The method for processing the substrate according to claim 1,
wherein the surfactant is at least one selected from the group consisting of a compound represented by formula (2a), a compound represented by formula (2b), and a compound represented by formula (2c), 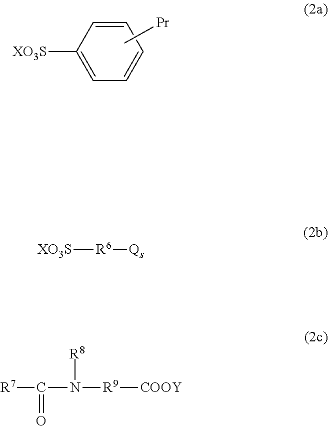
wherein R⁶ represents an alkylene group, R⁷ and R⁸ each independently represents an alkyl group having 1 to 20 carbon atoms, R⁹ represents an alkylene group having 1 to 10 carbon atoms, X represents H, Na, K, or NH₄, Y represents H, Na, or K, P and Q each independently represents a monovalent organic group, r represents a number from 0 to 5, and s represents a number from 0 to 3.

6. The method for processing the substrate according to claim 1,
wherein the first chemical solution comprises water.

7. The method for processing the substrate according to claim 1,
wherein the second chemical solution comprises water.

8. The method for processing the substrate according to claim 1,
wherein the first chemical solution comprises a water-based organic solvent.

9. The method for processing the substrate according to claim 1,
wherein the second chemical solution comprises a water-based organic solvent.

10. The method for processing the substrate according to claim 1,
wherein a content of the silane coupling agent in the first chemical solution is from 0.01 to 10% by mass.

11. The method for processing the substrate according to claim 1,
wherein a content of the surfactant in the second chemical solution is from 0.01 to 10% by mass.

12. A kit for processing a substrate, the kit being for processing a surface of an etched pattern on a substrate, the kit comprising:
a first chemical solution that is used for processing the surface of the pattern, the first chemical solution comprising a silane coupling agent that has a SP value of Hansen solubility parameter of 15 or more; and
a second chemical solution that is used for processing the surface of the pattern after the surface of the pattern is processed with the first chemical solution, the second chemical solution comprising an anionic or amphoteric surfactant.

13. A method for manufacturing a semiconductor substrate, comprising:
a step for preparing a substrate with an etched pattern, and
a step for processing a surface of the pattern of the substrate by the method for processing the substrate according to claim 1.
